(19) United States
(12) Patent Application Publication
(10) Pub. No.: US 2021/0136949 A1
(43) Pub. Date: May 6, 2021

(54) REMOTE HEAT EXCHANGING MODULE AND COMPOSITE THIN-LAYERED HEAT CONDUCTION STRUCTURE

(71) Applicant: Acer Incorporated, New Taipei City (TW)

(72) Inventors: Kuang-Hua Lin, New Taipei City (TW); Wen-Neng Liao, New Taipei City (TW)

(73) Assignee: Acer Incorporated, New Taipei City (TW)

(21) Appl. No.: 17/082,040

(22) Filed: Oct. 28, 2020

(30) Foreign Application Priority Data
Nov. 1, 2019 (TW) 108139792

(51) Int. Cl. H05K 7/20; B32B 9/00; B32B 9/04; B32B 15/04

(52) U.S. Cl. CPC H05K 7/2039; H05K 7/20136; B32B 9/007; B32B 9/041; B32B 2457/08; B32B 2250/03; B32B 2250/40; B32B 2307/302; B32B 15/04

(57) ABSTRACT

A remote heat exchanging module is configured to dissipate heat of a heat source and includes a first heat conduction member, a second heat conduction member, and a heat dissipation member. The first heat conduction member includes a first metallic layer in thermal contact with the heat source, a second metallic layer including a first end and a second end opposite to each other, and a graphene layer located between the first and the second metallic layers. The first end is in thermal contact with the second metallic layer. The heat dissipation member is in thermal contact with the second end. Heat generated by the heat source is transferred to the second end sequentially through the first heat conduction member and the first end and is dissipated out of the remote heat exchanging module through the heat dissipation member. A composite thin-layered heat conduction structure is also provided.

### CROSS-REFERENCE TO RELATED APPLICATION

This application claims the priority benefit of Taiwan application serial no. 108139792, filed on Nov. 1, 2019. The entirety of the above-mentioned patent application is hereby incorporated by reference herein and made a part of this specification.

### BACKGROUND OF THE INVENTION

### 1. Field of the Invention

The invention relates to a heat dissipation module and a heat conduction structure, and in particular, to a remote heat exchanging module and a composite thin-layered heat conduction structure.

### 2. Description of Related Art

At present, Currently, electronic apparatuses, such as portable computers, tablet computers, smartphones, and navigators and the like are able to provide powerful functions at a fast computing speed in reduced sizes. As a result, the electronic apparatuses emit more heat, or heat emission points are more concentrated. Therefore, to enable the electronic apparatuses to maintain good operating efficiency, heat dissipation design for the electronic apparatuses is particularly important.

Generally, various heat dissipation materials are widely used in the electronic apparatuses, and different heat dissipation materials exhibit different performance. For example, metallic materials such as copper, aluminum, and silver are widely applied because of a good heat conduction property and are made into related heat dissipation elements. In addition, a graphene material may also be used as a heat conduction medium. However, as limited by a mechanical property of the graphene material that a structure of the graphene material is brittle and is not ductile, it is difficult to perform post-processing on the graphene material, and it is difficult to combine the graphene material with common heat dissipation elements in the electronic apparatuses.

In view of this, how to provide a mechanism to smoothly combine the graphene material with other heat dissipation elements becomes a problem to be thought about and solved by related technical persons in the art.

### SUMMARY OF THE INVENTION

The invention provides a remote heat exchanging module and a composite thin-layered heat conduction structure, where a heat conduction member or a thin-layered heat conduction structure formed by cladding a graphene layer between metallic layers is mechanically characterized by both high heat dissipation efficiency and applicability to processing and combination.

The remote heat exchanging module of the invention is configured to dissipate heat of a heat source. The remote heat exchanging module includes a first heat conduction member, a second heat conduction member, and a heat dissipation member. The first heat conduction member includes a first metallic layer, a second metallic layer, and a graphene layer. The graphene layer is located between the first metallic layer and the second metallic layer, and the first metallic layer is in thermal contact with the heat source. The second heat conduction member includes a first end and a second end opposite to each other. The first end is in thermal contact with the second metallic layer. The heat dissipation member is in thermal contact with the second end. Heat generated by the heat source is transferred to the second end sequentially through the first heat conduction member and the first end of the second heat conduction member, and is dissipated out of the remote heat exchanging module by the heat dissipation member.

The composite thin-layered heat conduction structure of the invention includes a first metallic layer, a graphene layer, and a second metallic layer seamlessly attached to one another. The graphene layer is clad between the first metallic layer and the second metallic layer. A heat source is in thermal contact with the first metallic layer, so that heat generated by the heat source is transferred to the second metallic layer sequentially through the first metallic layer and the graphene layer.

Based on the above, the composite thin-layered heat conduction structure and the remote heat exchanging module including the composite thin-layered heat conduction structure are applicable to a light, thin and small portable electronic apparatus. Further, because the first heat conduction member is a composite thin-layered heat conduction structure consisting of the first metallic layer, the graphene layer, and the second metallic layer, a protection effect is provided by the metallic layers on an outer side while a great heat conduction characteristic of the graphene layer is used. In addition, because of ductility of the metallic layers, the first heat conduction member can be easily post-processed and assembled, and the graphene layer can be prevented from being easily damaged by an external force.

To make the features and advantages of the invention more comprehensible, a detailed description is made below with reference to accompanying drawings by using embodiments.

### BRIEF DESCRIPTION OF THE DRAWINGS

FIG. 1 is a schematic view of a remote heat exchanging module according to an embodiment of the invention.

FIG. 2 is an exploded view of a first heat conduction member in FIG. 1.

FIG. 3 is a partial cross-sectional view of a remote heat exchanging module according to another embodiment.

FIG. 4 is a line graph of heat dissipation efficiency of a remote heat exchanging module.

### DESCRIPTION OF THE EMBODIMENTS

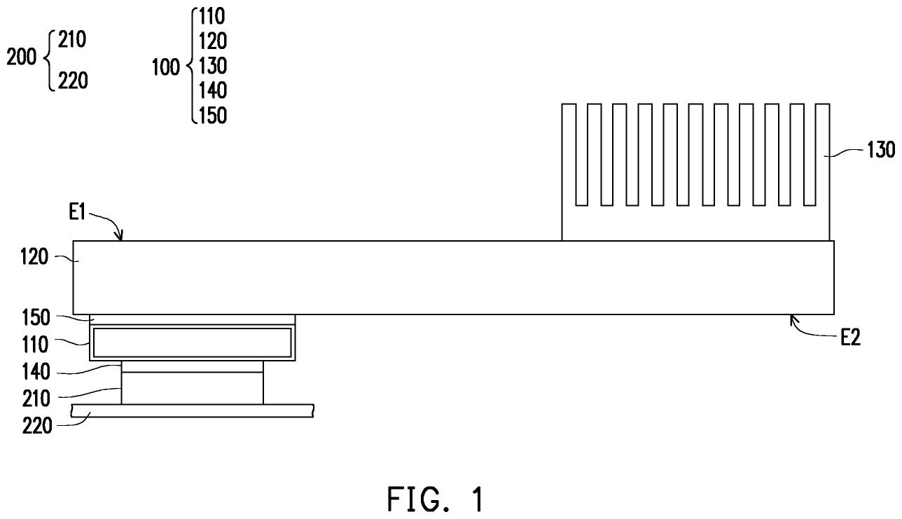

FIG. 1 is a schematic view of a remote heat exchanging module according to an embodiment of the invention, which provides a simple schematic of related components of the present embodiment from a side view. Referring to FIG. 1, in the present embodiment, a remote heat exchanging module 100 is configured to dissipate heat of a heat source 200. The remote heat exchanging module 100 includes a first heat conduction member 110, a second heat conduction member 120, and a heat dissipation member 130. The first conduction member 110 is in thermal contact with the heat source 200, and the second heat conduction member 120 is in thermal contact between the first conduction member 110 and the heat dissipation member 130. Heat generated by the heat source 200 is sequentially transferred to the first heat conduction member 110 and the second heat conduction member 120, and then is dissipated by the heat dissipation member 130. In this way, the heat is discharged from the remote heat exchanging module 100. Because inner space of a portable electronic apparatus is limited, a problem of system heat dissipation needs to be solved through heat exchange. In addition, the portable electronic apparatus may appear light, thin, and small because the remote heat exchanging module 100 is applied.

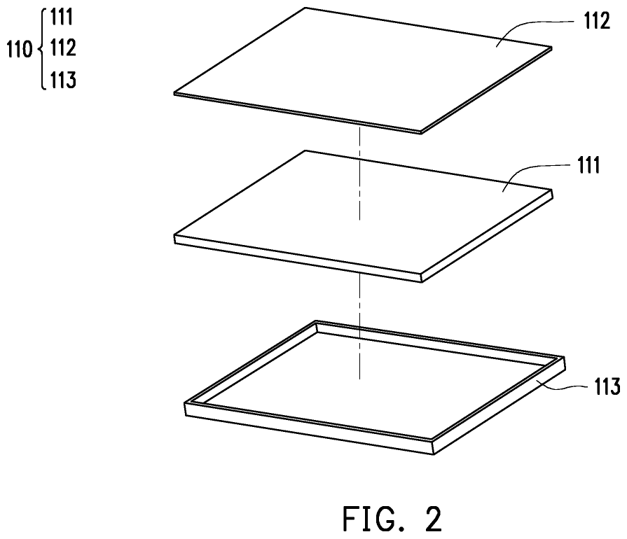

FIG. 2 is an exploded view of the first heat conduction member in FIG. 1. Referring to FIG. 1 and FIG. 2 together, specifically, the heat source 200 of the present embodiment includes an electronic chip 210 packaged on a circuit board 220. The electronic chip 210 is, for example, a central processing unit (CPU) or a graphics processing unit (GPU). The first heat conduction member 110 of the present embodiment includes a first metallic layer 113, a second metallic layer 112, and a graphene layer 111. The graphene layer 111 is located between the first metallic layer 113 and the second metallic layer 112. In this case, the first metallic layer 113 includes an accommodating space to accommodate the graphene layer 111 and is configured to be combined with the second metallic layer 112, so that the first metallic layer 113, the second metallic layer 112, and the graphene layer 111 are seamlessly attached to one another. In the present embodiment, the first metallic layer 113, the second metallic layer 112, and the graphene layer 111 may be combined through adhesion, but the combination manner is not limited thereto.

In this way, the first metallic layer 113 is in thermal contact with the heat source 200. The second heat conduction member 120 includes a first end E1 and a second end E2 opposite to each other. The first end E1 is in thermal contact with the second metallic layer 112. The heat dissipation member 130 is, for example, a heat dissipation fin, and is in thermal contact with the second end E2. Correspondingly, the heat generated by the heat source 200 is transferred to the second end E2 sequentially through the first heat conduction member 110 and the first end E1 of the second heat conduction member 120 and is dissipated out of the remote heat exchanging module 100 through heat convection of the heat dissipation member 130.

It should be further noted that, the first heat conduction member 110 obtained through combination in the foregoing manner includes the graphene layer 111 with a great heat conductivity (the heat conductivity is greater than 1,000 W/mK), and may be easily processed because of the first metallic layer 113 and the second metallic layer 112 on an outer side. That is, to improve efficiency of thermal contact (and conduction) between the first heat conduction member 110 and the heat source 200, the remote heat exchanging module 100 of the present embodiment further includes a soldering material 150 and a heat conduction material (a thermal interface material) 140 to smoothly combine the first heat conduction member 110 with the heat source 200 and the second heat conduction member 120 without correspondingly reducing heat transfer efficiency.

In the present embodiment, the heat conduction material 140 is, for example, a thermal grease, a thermal conductive adhesive, a thermal gap filler, a thermally conductive pad, a thermal tape, a phase change material, or a phase change metal alloy, and is disposed between the electronic chip 210 of the heat source 200 and the first metallic layer 113, to reduce thermal contact resistance between the components. In addition, because component surfaces are rough to some extent, when surfaces of two components are in contact, the surfaces are impossibly in full contact and there are always air gaps. A coefficient of heat conductivity of air is small, leading to great thermal contact resistance between the electronic chip 210 of the heat source 200 and the first metallic layer 113. Therefore, the heat conduction material 140 may be used to fill the air gaps to reduce the thermal contact resistance and improve heat dissipation performance.

In addition, because the graphene layer 111 is clad with the second metallic layer 112, the first end E1 of the second heat conduction member 120 can be easily combined with the second metallic layer 112 via the soldering material 150 (through soldering). In addition, because the soldering material 150 has a great thermal conduction characteristic and can be seamlessly disposed between the second metallic layer 112 and the second heat conduction member 120, a low thermal contact resistance state between the second heat conduction member 120 and the second metallic layer 112 can be maintained.

It should be further noted that, in the first heat conduction member of the present embodiment, because a density of the graphene layer 111 is 2.2 g/cm³, compared with a heat dissipation element made of metal in the prior art, the graphene layer 111 is essentially lighter than the metal, which helps to reduce an overall weight of the first heat conduction member 110, so that the remote heat exchanging module 100 of the present embodiment is more suitable to be applied to a light, thin and small portable electronic apparatus.

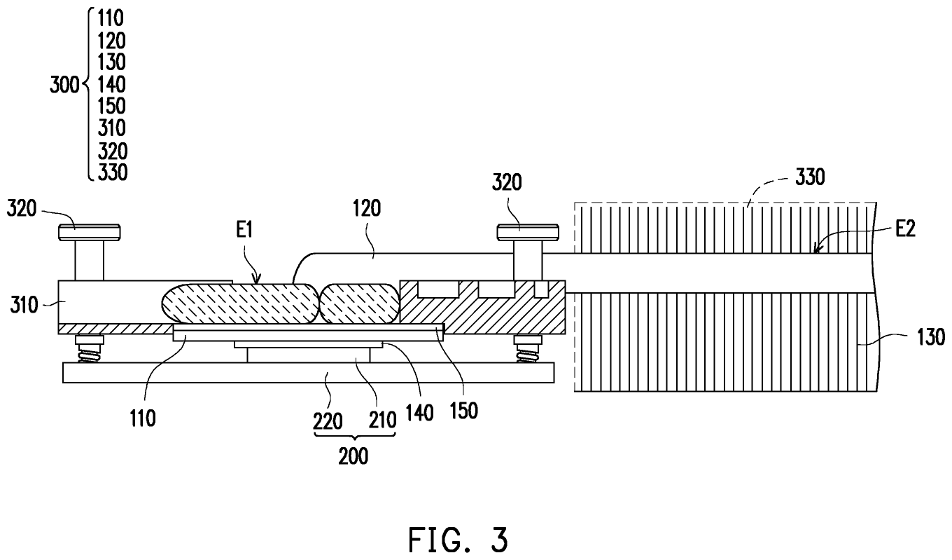

FIG. 3 is a partial cross-sectional view of a remote heat exchanging module according to another embodiment. Referring to FIG. 3, in the present embodiment, components identical with those in the foregoing embodiments are shown with same reference numerals, and a difference therebetween is as follows: a remote heat exchanging module 300 further includes a carrier 310, a locking member 320, and a fan 330. The first heat conduction member 110 and the first end E1 of the second heat conduction member 120 are assembled to the carrier 310 and the carrier 310 is assembled to the circuit board 220, so that the first heat conduction member 110 is abutted between the carrier 310 and the electronic chip 210 of the heat source 200. Similarly, the heat generated by the heat source 200 is transferred to the heat dissipation member 130 (the thermal fin) sequentially through the heat conduction material 140, the first heat conduction member 110, the soldering material 150, and the first end E1 and the second end E2 of the second heat conduction member 120, and then the fan 330 provides an airflow to force the heat dissipation 130 to perform heat exchange, to discharge the heat out of the remote heat exchanging module 300. It can be known from the embodiments shown in FIG. 1 and FIG. 3 that, the remote heat exchanging module 100 and the remote heat exchanging module 300 are applicable to a heat dissipation mechanism of natural convection and forced convection.

Further, the carrier 310 of the present embodiment is a heat sink, including a hollow portion to receive the first heat conduction member 110 and the second heat conduction member 120 for thermal contact via the hollow portion. Certainly, same as the foregoing embodiment, the second metallic layer 112 of the first heat conduction member 110 and the first end E1 of the second heat conduction member 120 are combined with each other in the hollow portion via the soldering material 150. In addition, because the carrier 310 is assembled to the circuit board 220 by using the locking member 320, and the first heat conduction member 110 is obtained by cladding the graphene layer 111 with the first metallic layer 113 and the second metallic layer 112, during assembly, the carrier 310 may be more smoothly abutted on the first heat conduction member 100, and by clamping the graphene layer 111 between the first metallic layer 113 and the second metallic layer 112 that are ductile, it does not need to be worried that the graphene layer 111 is damaged by an external assembly force.

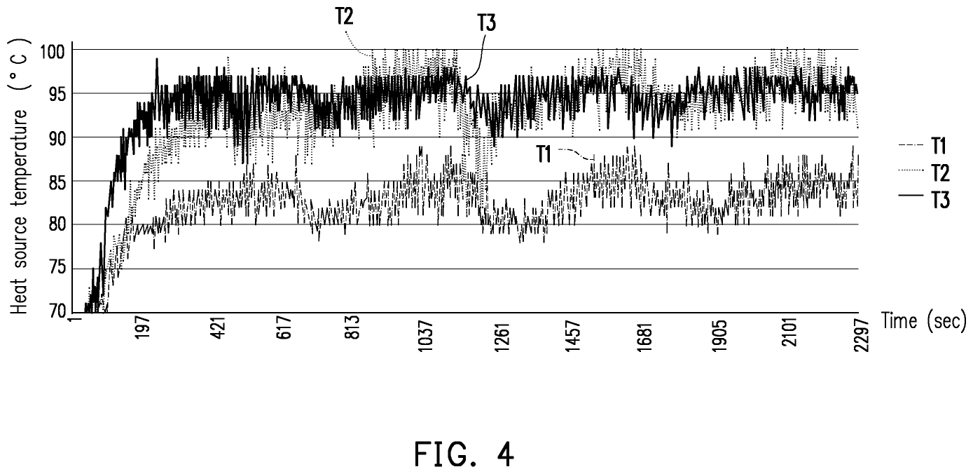

FIG. 4 is a line graph of heat dissipation efficiency of a remote heat exchanging module. In FIG. 4, heat dissipation is performed on a heat source with a high power (100 W) separately by the remote heat exchanging module 100 or the remote heat exchanging module 300 (shown as a curve T1), and a copper heat dissipation plate (shown as a curve T2) and a vapor chamber (shown as a curve T3) in the prior art, and heat dissipation efficiency of the technologies is compared by measuring a heat source temperature. Referring to FIG. 4, it can be clearly known that, because the first heat conduction member 110 is provided with the graphene layer 111, the remote heat exchanging module 100 or the remote heat exchanging module 300 reduces the heat source temperature 10° C. more than the other two, and accordingly, it can be calculated that a heat dissipation capability may be improved by 15%. That is, compared with the heat dissipation technologies using only the copper heat dissipation plate or the vapor chamber, the invention can efficiently reduce thermal contact resistance between thermal transfer components via a great heat conduction characteristic of the graphene layer, and prevent a component temperature from soaring because of heat congestion on a heat transfer path of the remote heat exchanging module 100 or the remote heat exchanging module 300. Concentrated hot points can be rapidly dispersed to achieve a good thermal diffusion effect, thereby relieving local overheating, and improving service life of related components.

Based on the above, in the embodiments of the invention, the remote heat exchanging module is applicable to a light, thin and small portable electronic apparatus. Further, because the first heat conduction member is a composite thin-layered heat conduction structure consisting of the first metallic layer, the graphene layer, and the second metallic layer, a protection effect is provided by the metallic layers on an outer side while a great heat conduction characteristic of the graphene layer is used. In addition, because of ductility of the metallic layers, the first heat conduction member can be easily post-processed and assembled, and the graphene layer can be prevented from being damaged by an external force. In other words, the first heat conduction member can correspondingly be smoothly combined with the second heat conduction member through soldering, and be in thermal contact with the heat source via the heat conduction material. More importantly, locking between the carrier and the circuit board may be further used in structural assembly, so that the first heat conduction member is abutted between the carrier and the heat source, to achieve both assembly convenience and a good heat conduction property. In this way, integrity of the graphene layer is maintained, and component combination and assembly are easier, thereby improving heat dissipation efficiency and service life.

Although the invention has been disclosed with reference to the above embodiments, the embodiments are not intended to limit the invention. A person of ordinary skill in the art may make variations and improvements without departing from the spirit and scope of the invention. Therefore, the protection scope of the invention should be subject to the appended claims.

What is claimed is:

1. A remote heat exchanging module, configured to dissipate heat of a heat source, the remote heat exchanging module comprising:
a first heat conduction member, comprising a first metallic layer, a second metallic layer, and a graphene layer, wherein the graphene layer is located between the first metallic layer and the second metallic layer, and the first metallic layer is in thermal contact with the heat source;
a second heat conduction member, comprising a first end and a second end opposite to each other, wherein the first end is in thermal contact with the second metallic layer; and
a heat dissipation member in thermal contact with the second end, wherein heat generated by the heat source is transferred to the second end of the second heat conduction member sequentially through the first heat conduction member and the first end of the second heat conduction member and is dissipated out of the remote heat exchanging module through the heat dissipation member.

2. The remote heat exchanging module according to claim 1, wherein the heat source comprises an electronic chip packaged on a circuit board, the remote heat exchanging module further comprises a carrier, the first heat conduction member and the first end of the second heat conduction member are assembled to the carrier, and the carrier is assembled to the circuit board, so that the first heat conduction member is abutted between the carrier and the heat source.

3. The remote heat exchanging module according to claim 2, wherein the carrier is a heat sink.

4. The remote heat exchanging module according to claim 1, further comprising a soldering material, wherein the first end of the second heat conduction member and the second metallic layer are combined with each other via the soldering material.

5. The remote heat exchanging module according to claim 1, further comprising a heat conduction material filled between the first metallic layer and the heat source.

6. The remote heat exchanging module according to claim 1, wherein the first heat conduction member is a composite thin-layered heat conduction structure with a thickness of 0.05 mm to 0.1 mm, a heat conductivity of the graphene layer is greater than 1,000 W/mK, and a density of the graphene layer is 2.2 g/cm³.

7. The remote heat exchanging module according to claim 1, wherein the second heat conduction member is a heat pipe or a vapor chamber.

8. The remote heat exchanging module according to claim 1, further comprising a fan, disposed beside the second heat conduction member to dissipate the heat transferred to the second end.

9. A composite thin-layered heat conduction structure, comprising a first metallic layer, a graphene layer, and a second metallic layer seamlessly attached to one another, wherein the graphene layer is clad between the first metallic layer and the second metallic layer, and a heat source is adapted to be in thermal contact with the first metallic layer, so that heat generated by the heat source is transferred to the second metallic layer sequentially through the first metallic layer and the graphene layer.

10. The composite thin-layered heat conduction structure according to claim 9, wherein a thickness of the composite thin-layered heat conduction structure is 0.05 mm to 0.1 mm, a heat conductivity of the graphene layer is greater than 1,000 W/mK, and a density of the graphene layer is 2.2 g/cm³.
